(19) United States
(12) Patent Application Publication
(10) Pub. No.: US 2026/0101798 A1
(43) Pub. Date: Apr. 9, 2026

(54) SEMICONDUCTOR DEVICE AND METHOD FOR PRODUCING SEMICONDUCTOR DEVICE

(71) Applicant: Rohm Co., Ltd., Kyoto-shi (JP)

(72) Inventor: Kensei TAKAMOTO, Kyoto-shi (JP)

(21) Appl. No.: 19/404,938

(22) Filed: Dec. 1, 2025

Related U.S. Application Data
(63) Continuation of application No. PCT/JP2024/017398, filed on May 10, 2024.

(30) Foreign Application Priority Data
Jun. 8, 2023 (JP) 2023-094659

(51) Int. Cl. H10W 72/60; H10W 70/40; H10W 72/00; H10W 90/00

(52) U.S. Cl. CPC H10W 72/634; H10W 70/417; H10W 72/07636; H10W 72/627; H10W 72/637; H10W 90/736; H10W 72/886

(57) ABSTRACT

A semiconductor device includes a semiconductor element having a first electrode and a second electrode, a first conductive member being located on a first side in a thickness direction with respect to the first electrode and having a first reverse surface to face a second side in the thickness direction, a second conductive member being located on the first side in the thickness direction with respect to the second electrode and having a second reverse surface to face the second side in the thickness direction, a first conductive bonding material interposed between the first electrode and the first reverse surface and bonded to the first electrode and the first conductive member, and a second conductive bonding material interposed between the second electrode and the second reverse surface and bonded to the second electrode and the second conductive member. An area of the second reverse surface is smaller than an area of the first reverse surface. A distance between the second electrode and the second reverse surface in the thickness direction is smaller than a distance between the first electrode and the first reverse surface in the thickness direction.

### TECHNICAL FIELD

The present disclosure relates to a semiconductor device and a method for manufacturing a semiconductor device.

### BACKGROUND ART

Various configurations of semiconductor devices incorporating semiconductor elements have been proposed. JP-A-2019-192751 discloses an example of a conventional semiconductor device. The semiconductor device disclosed in this document includes a plurality of leads and a semiconductor element. A source electrode (first electrode) and a gate electrode (second electrode) are formed on the element obverse surface of the semiconductor element. The source electrode and the gate electrode each have a pad portion of a lead bonded thereto via a bonding material.

In the semiconductor element of the semiconductor device described in JP-A-2019-192751, the area of the gate electrode is smaller than the area of the source electrode, and the bonding area of the lead bonded to the gate electrode is smaller than the bonding area of the lead bonded to the source electrode. The distance between each electrode and the bonding surface of the lead bonded thereto may be subject to dimensional errors. If the distance between the relatively smaller gate electrode and the bonding surface of the lead bonded thereto becomes larger than the specified dimension, there is concern that bonding defects or other issues may occur at the bonding interface between the gate electrode and the lead.

### BRIEF DESCRIPTION OF THE DRAWINGS

FIG. 1 is a perspective view showing a semiconductor device according to a first embodiment of the present disclosure.

FIG. 2 is a perspective view of main parts showing the semiconductor device according to the first embodiment of the present disclosure.

FIG. 3 is a plan view showing the semiconductor device according to the first embodiment of the present disclosure.

FIG. 4 is a plan view of main parts showing the semiconductor device according to the first embodiment of the present disclosure.

FIG. 5 is a bottom view showing the semiconductor device according to the first embodiment of the present disclosure.

FIG. 6 is a bottom view of main parts showing the semiconductor device according to the first embodiment of the present disclosure.

FIG. 7 is a side view showing a semiconductor device according to the first embodiment of the present disclosure.

FIG. 8 is a cross-sectional view along line VIII-VIII in FIG. 4.

FIG. 9 is a cross-sectional view along line IX-IX in FIG. 4.

FIG. 10 is a cross-sectional view along line X-X in FIG. 4.

FIG. 11 is a partially enlarged view of FIG. 8.

FIG. 12 is a partially enlarged view of FIG. 9.

FIG. 13 is a plan view showing one process during the manufacture of the semiconductor device according to the first embodiment of the present disclosure.

FIG. 14 is a plan view showing a process following that in FIG. 13.

FIG. 15 is a partially enlarged side view showing the process shown in FIG. 14.

FIG. 16 is a partially enlarged side view showing a process following the process shown in FIG. 15.

FIG. 17 is a plan view of main parts showing a semiconductor device according to a second embodiment of the present disclosure.

FIG. 18 is a cross-sectional view along line XVIII-XVIII in FIG. 17.

FIG. 19 is a partially enlarged view of FIG. 18.

FIG. 20 is a plan view of main parts showing a semiconductor device according to a third embodiment of the present disclosure.

### DETAILED DESCRIPTION OF EMBODIMENTS

The preferred embodiments of the present disclosure will now be described in detail with reference to the drawings.

The terms "first," "second," "third," etc., in the present disclosure are used merely as labels and do not necessarily imply any particular order of the objects they refer to.

In the present disclosure, unless otherwise specified, "object A is formed at object B" and "object A is formed on object B" include both "object A being directly formed on object B" and "object A being formed on object B with another object interposed between them." Similarly, unless otherwise specified, "object A is placed at object B" and "object A is placed on object B" include both "object A being directly placed on object B" and "object A being placed on object B with another object interposed between them." Similarly, unless otherwise specified, "object A is located on object B" includes both "object A is located on object B while contacting it" and "object A is located on object B with another object interposed between them." Furthermore, unless otherwise specified, "object A overlaps object B in a certain direction" includes both "object A overlapping all of object B" and "object A overlapping a part of object B." Furthermore, in the present disclosure, "a surface A faces direction B (either one side or the other)" is not limited to cases where the angle between surface A and direction B is 90°, but also includes cases where surface A is inclined with respect to direction B.

### First Embodiment:

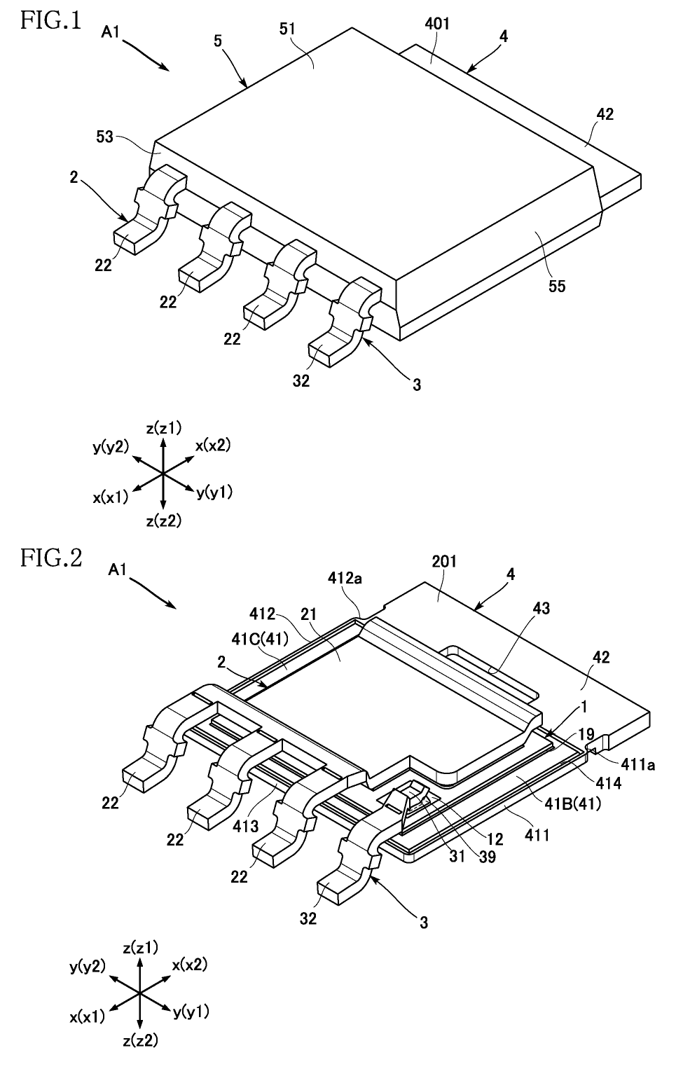

FIGS. 1 to 12 illustrate a semiconductor device according to a first embodiment of the present disclosure. The semiconductor device A1 of the present embodiment includes a semiconductor element 1, a first conductive member 2, a second conductive member 3, a third conductive member 4, and a sealing resin 5. The semiconductor device A1 further includes a conductive bonding material 19, a first conductive bonding material 29, and a second conductive bonding material 39. The application of the semiconductor device A1 is not limited in any way and may be used, for example, in electronic devices equipped with power conversion circuits such as DC-DC converters.

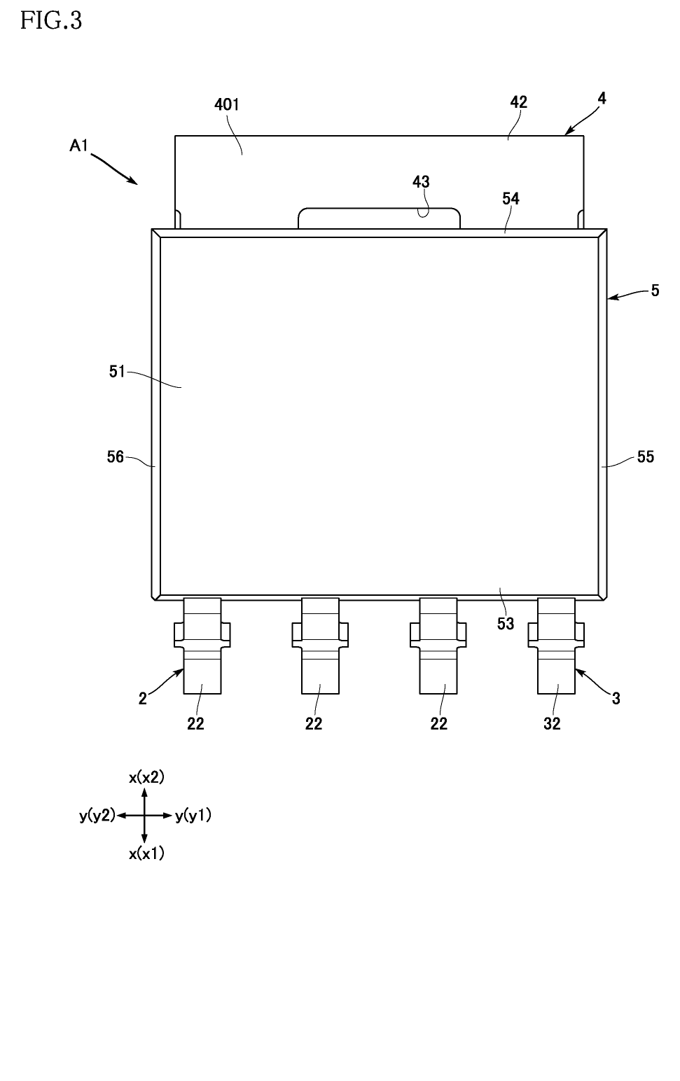

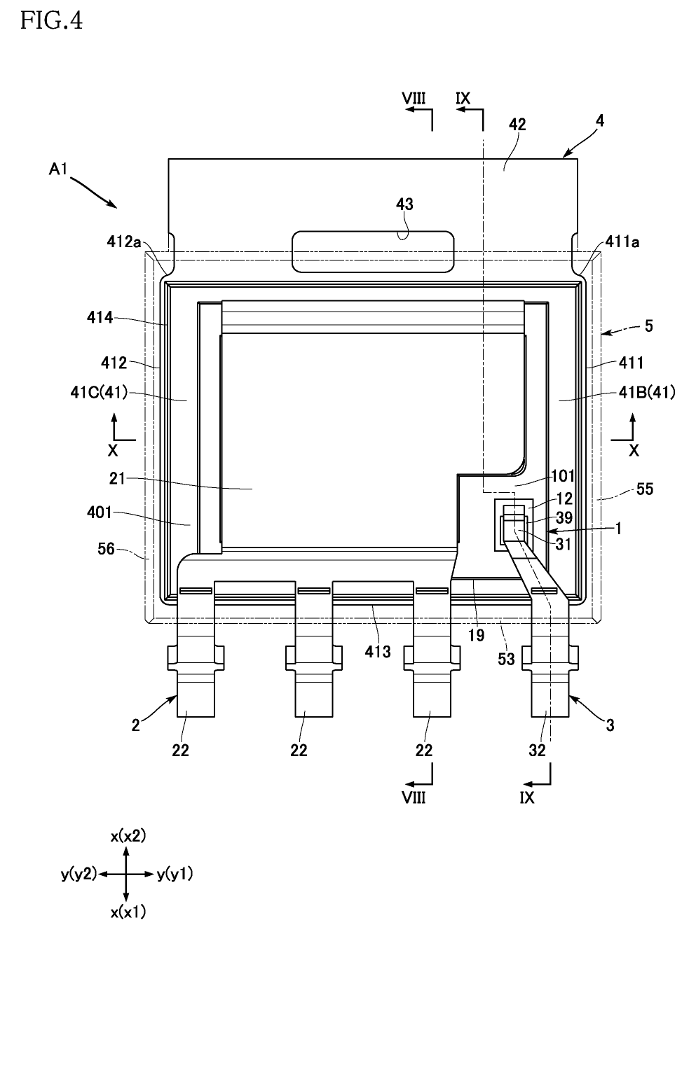

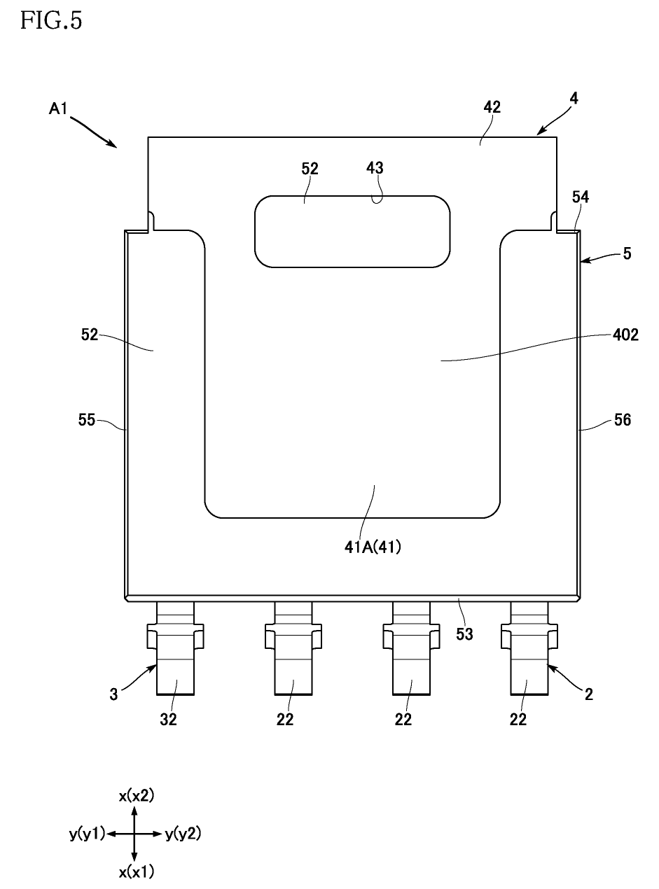

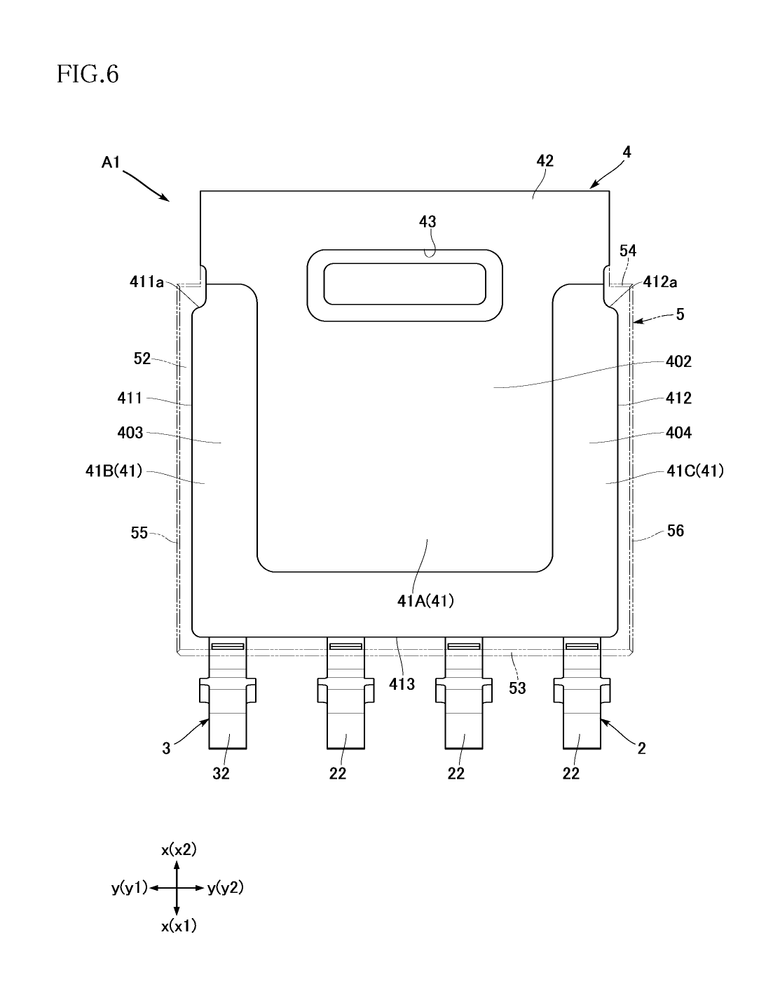

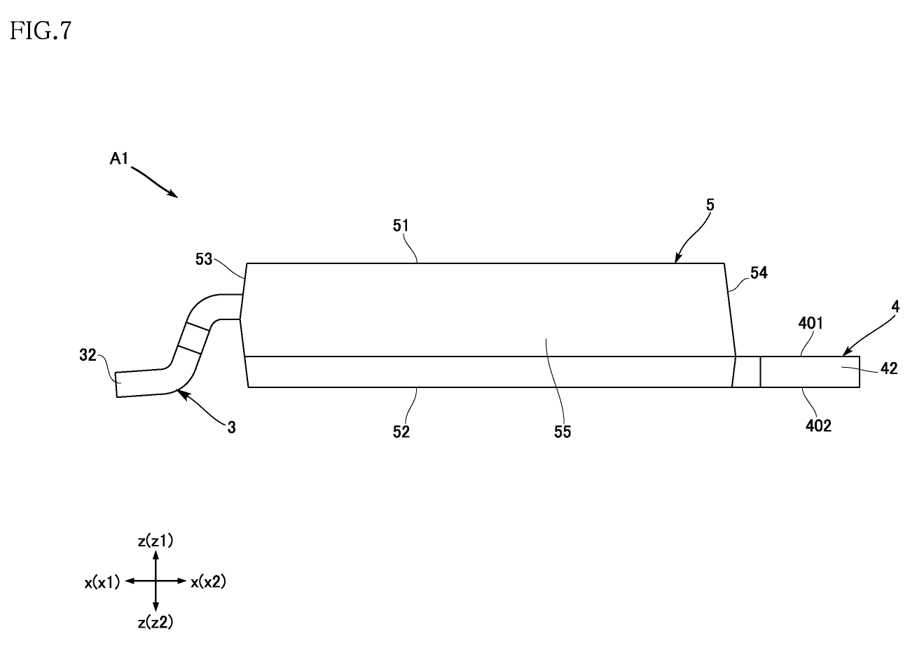

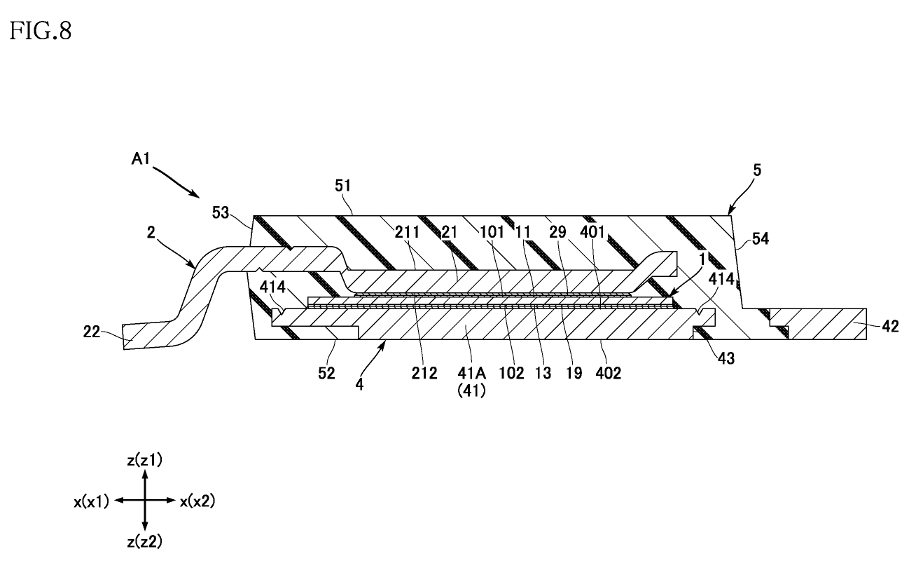

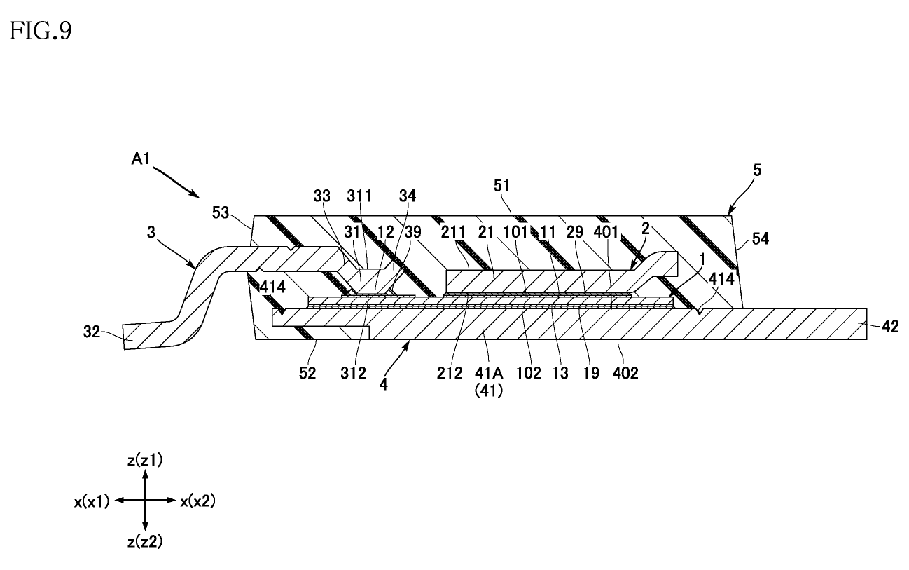

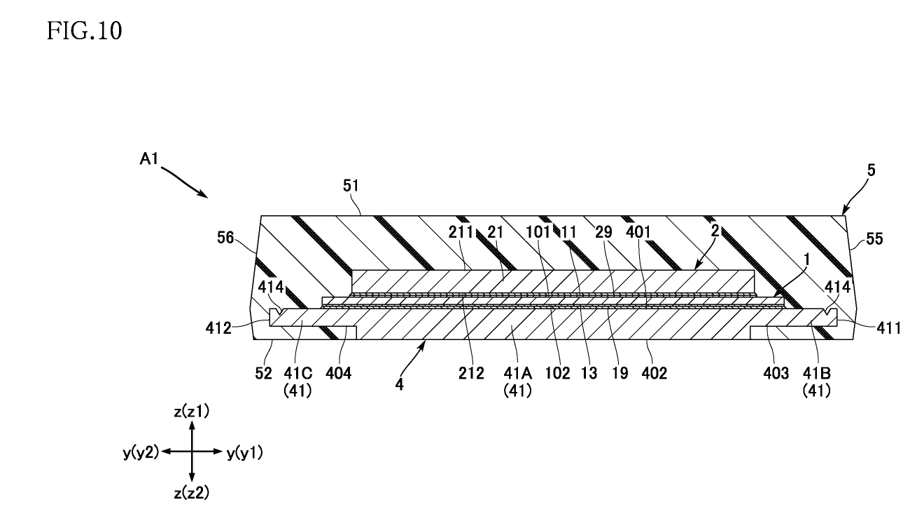

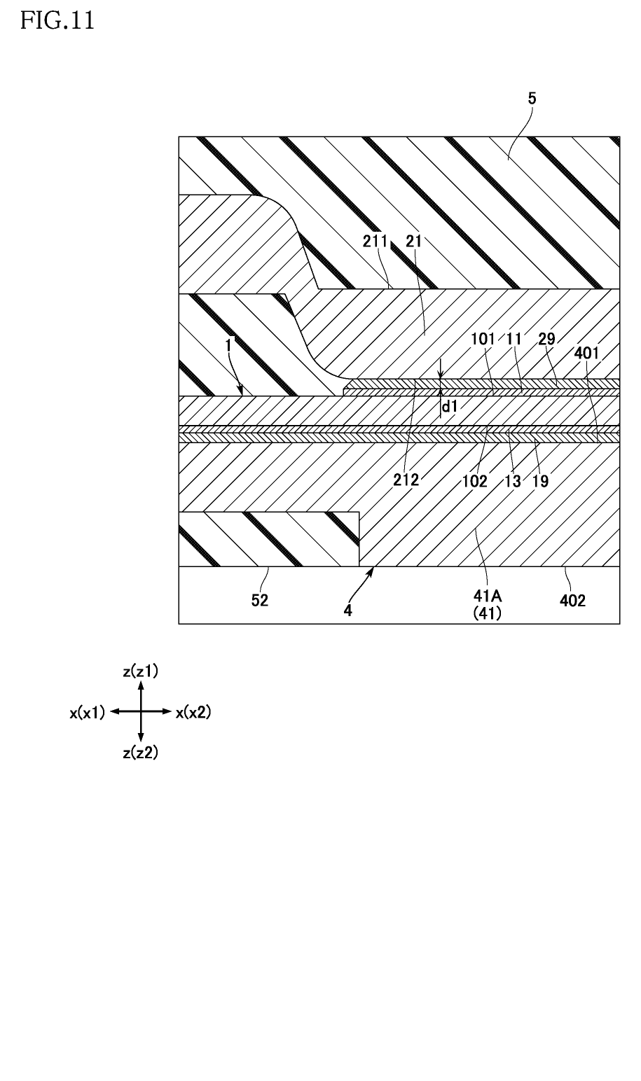

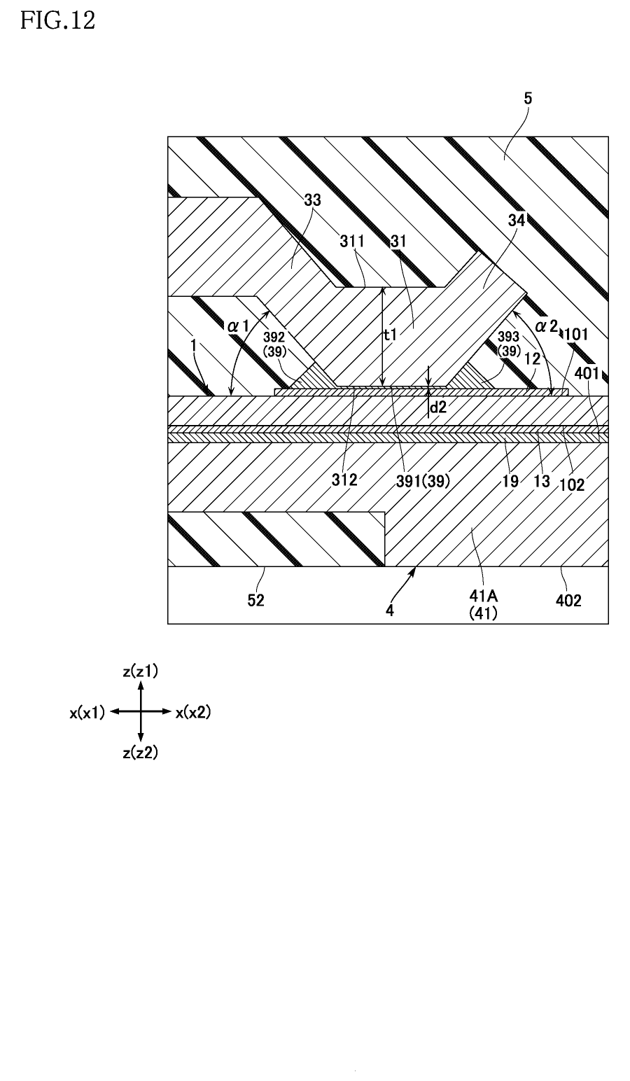

FIG. 1 is a perspective view of the semiconductor device A1. FIG. 2 is a perspective view of main parts of the semiconductor device A1, omitting the sealing resin 5. FIG. 3 is a plan view of the semiconductor device A1. FIG. 4 is a plan view of main parts of the semiconductor device A1, showing the sealing resin 5 as being transparent. FIG. 5 is a bottom view of the semiconductor device A1. FIG. 6 is a bottom view of main parts of the semiconductor device A1, showing the sealing resin 5 as being transparent. FIG. 7 is a side view of the semiconductor device A1. FIG. 8 is a cross-sectional view along line VIII-VIII in FIG. 4. FIG. 9 is a cross-sectional view along line IX-IX in FIG. 4. FIG. 10 is a cross-sectional view along line X-X in FIG. 4. FIG. 11 is a partially enlarged view of FIG. 8. FIG. 12 is a partially enlarged view of FIG. 9. It is a partially enlarged view of FIG. 4. Note that in FIGS. 4 and 6, the sealing resin 5 in transparency is shown by imaginary lines (dash-dot-dot line).

In these figures, for example, one instance of the thickness direction is referred to as the "thickness direction z". A direction orthogonal to the thickness direction z (the vertical direction in FIGS. 3 and 4) is an example of a first direction and is referred to as the "first direction x". A direction orthogonal to both the thickness direction z and the first direction x (the horizontal direction in FIGS. 3 and 4) is an example of a second direction and is referred to as the "second direction y". In FIGS. 3 and 4, the lower sides of the figures are examples of "one side in the first direction" and are referred to as the "x1 side in the first direction x". The upper sides of the figures are examples of "the other side in the first direction" and are referred to as the "x2 side in the first direction x". In FIGS. 3 and 4, the right sides of the figures are referred to as the "y1 side in the second direction y," and the left sides of the figures are referred to as the "y2 side in the second direction y." Furthermore, in FIGS. 8 to 10, the upper sides of the figure are examples of "one side in the thickness direction" and are referred to as the "z1 side in the thickness direction z". The lower sides of the figures are examples of "the other side in the thickness direction" and are referred to as the "z2 side in the thickness direction z".

The semiconductor element 1 is an element that performs the electrical function of the semiconductor device A1. In the present embodiment, the semiconductor element 1 is a three-terminal element having three electrodes, and is, for example, a MOSFET (Metal-Oxide-Semiconductor Field-Effect Transistor). Alternatively, the semiconductor element 1 may be a switching element such as an IGBT (Insulated Gate Bipolar Transistor) or a diode. For the description of the semiconductor device A1, the semiconductor element 1 is an n-channel MOSFET with a vertical structure. The semiconductor element 1 is rectangular as viewed in the thickness direction z.

As shown in FIGS. 2, 4, and 8 to 10, the semiconductor element 1 has an element first surface 101, an element second surface 102, a first electrode 11, a second electrode 12, and a third electrode 13. The element first surface 101 and the element second surface 102 are spaced apart in the thickness direction z and face away from each other. The element first surface 101 faces the z1 side in the thickness direction z. The element second surface 102 faces the z2 side in the thickness direction z.

The first electrode 11 is placed on the element first surface 101. A current corresponding to the electrical power converted by the semiconductor element 1 flows through the first electrode 11. That is, the first electrode 11 corresponds to the source electrode of the semiconductor element 1.

The second electrode 12 is placed on the element first surface 101. A gate voltage for driving the semiconductor element 1 is applied to the second electrode 12. That is, the second electrode 12 corresponds to the gate electrode of the semiconductor element 1. As viewed in the thickness direction z, the area of the second electrode 12 is smaller than the area of the first electrode 11.

The third electrode 13 is placed on the element first surface 101. A current corresponding to the power before conversion by the semiconductor element 1 flows through the third electrode 13. That is, the third electrode 13 corresponds to the drain electrode of the semiconductor element 1.

The first conductive member 2 includes a portion placed on the z₁ side in the thickness direction z with respect to the semiconductor element 1. The first conductive member 2 includes a conductive material such as a metal and is constituted, for example, by a metal plate. The constituent material of the first conductive member 2 includes, for example, Cu (copper). The first conductive member 2 is a metal plate appropriately bent. As shown in FIGS. 1 to 6 and 8 to 10, the first conductive member 2 has a pad portion 21 and a plurality of terminal portions 22.

The pad portion 21 is the section conductively bonded to the first electrode 11 of the semiconductor element 1. The shape and size of the pad portion 21 are not limited in any way. In the illustrated example, as viewed in the thickness direction z, it has a shape overlapping most of the first electrode 11 and exposing the second electrode 12.

As shown in FIGS. 8 to 11, the pad portion 21 has a first obverse surface 211 and a first reverse surface 212. The first obverse surface 211 is a surface facing the z1 side in the thickness direction z. The first reverse surface 212 is a surface facing the z2 side in the thickness direction z.

As shown in FIGS. 8 to 11, the first electrode 11 of the semiconductor element 1 is bonded to the first reverse surface 212 of the pad portion 21 via the first conductive bonding material 29. The pad portion 21 and the first electrode 11 are conductively bonded via the first conductive bonding material 29. The constituent material of the first conductive bonding material 29 is not particularly limited and may be, for example, solder (a metal containing tin and silver). Furthermore, the first conductive bonding material 29 may also be constituted by metal paste containing metal such as silver (Ag). As shown in FIG. 11, the distance (first distance d1) between the first electrode 11 and the first reverse surface 212 in the thickness direction z is, for example, 5 μm or more and 30 μm or less. A plating layer composed of silver (Ag), for example, may be formed on the area of the pad portion 21 that is bonded to the semiconductor element 1 (first electrode 11).

The plurality of terminal portions 22 are connected to the pad portion 21 on the x1 side in the first direction x. Each terminal portion 22 extends in the first direction x as viewed in the thickness direction z and is arranged at intervals in the second direction y. The number of terminal portions 22 is not limited in any way, and it may be three as shown in the example, two, or four or more. A configuration with only one terminal portion 22 is also possible. As shown in FIGS. 1, 2, and 8, the terminal portion 22 has a portion connected to the pad portion 21 and covered by the sealing resin 5, a portion protruding from the sealing resin 5 toward the x1 side in the first direction x, a portion folded back toward the z2 side in the thickness direction z, and a portion located on the z2 side in the thickness direction z. The plurality of terminal portions 22 are used as terminals when mounting the semiconductor device A1. The plurality of terminal portions 22 are conducted to the first electrode 11 of the semiconductor element 1. The plurality of terminal portions 22 are the source terminals of the semiconductor device A1.

A plating layer composed of an alloy including tin (Sn), for example, as its main component, may be formed on the portion of the first conductive member 2 (the plurality of terminal portions 22) exposed from the sealing resin 5.

The second conductive member 3 includes a portion located on the z₁ side in the thickness direction z with respect to the semiconductor element 1. The second conductive member 3 contains a conductive material such as a metal and is, for example, constituted by a metal plate. The constituent material of the second conductive member 3 includes, for example, Cu (copper). The second conductive member 3 is a metal plate appropriately bent. As shown in FIGS. 1 to 7, FIG. 9, and FIG. 12, the second conductive member 3 has a first pad portion 31, a terminal portion 32, a first bent portion 33, and a second bent portion 34.

The first pad portion 31 is the section conductively bonded to the second electrode 12 of the semiconductor element 1. The shape and size of the first pad portion 31 are not limited in any way. In the illustrated example, as viewed in the thickness direction z, it has a shape overlapping a portion of the second electrode 12 and also exposing the second electrode 12.

As shown in FIGS. 9 and 12, the first pad portion 31 has a second obverse surface 311 and a second reverse surface 312. The second obverse surface 311 is a surface facing the z1 side in the thickness direction z. The second reverse surface 312 is a surface facing the z2 side in the thickness direction z. The area of the second reverse surface 312 is smaller than the area of the first reverse surface 212 of the pad portion 21 in the first conductive member 2.

The first bent portion 33 connects to the first pad portion 31 on the x1 side in the first direction x. The first bent portion 33 is inclined such that it extends toward the z1 side in the thickness direction z as it extends toward the x1 side in the first direction x. The second bent portion 34 connects to the x2 side in the first direction x with respect to the first pad portion 31. The second bent portion 34 is inclined such that it extends toward the z1 side in the thickness direction z as it extends toward the x2 side in the first direction x. As shown in FIG. 12, the inclination angle α1 of the first bent portion 33 with respect to the first direction x and the inclination angle α2 of the second bent portion 34 with respect to the first direction x are identical. Here, "the inclination angle α₁ and the inclination angle α₂ are identical" means that the inclination angle α₁ and the inclination angle α₂ are designed to be identical, and includes cases where the inclination angle α₁ and the inclination angle α₂ differ due to manufacturing errors, etc. The inclination angles α₁ and α₂ are not particularly limited, but in the illustrated example, the inclination angles α₁ and α₂ are approximately 45°.

As shown in FIGS. 9 and 12, the first pad portion 31, the first bent portion 33, and the second bent portion 34 are bonded to the second electrode 12 of the semiconductor element 1 via the second conductive bonding material 39. The first pad portion 31, the first bent portion 33, and the second bent portion 34 are conductively bonded to the second electrode 12 via the second conductive bonding material 39. In the present embodiment, the second conductive bonding material 39 includes a thin portion 391, a first portion 392, and a second portion 393. The thin portion 391 is interposed between the second electrode 12 and the second reverse surface 312 in the thickness direction z and is the portion contacting the second electrode 12 and the second reverse surface 312. The first portion 392 is located on the x1 side in the first direction x with respect to the thin portion 391 and contacts the second electrode 12 and the first bent portion 33. The second portion 393 is located on the x2 side in the first direction x with respect to the thin portion 391 and contacts the second electrode 12 and the second bent portion 34.

As shown in FIGS. 11 and 12, the distance (second distance d2) between the second electrode 12 and the second reverse surface 312 in the thickness direction z is smaller than the distance (first distance d1) between the first electrode 11 and the first reverse surface 212 in the thickness direction z. The second distance d2 between the second electrode 12 and the second reverse surface 312 in the thickness direction z is, for example, 1 μm or more and 20 μm or less. Note that the second electrode 12 and the second reverse surface 312 may partially contact each other. Furthermore, the ratio of the first distance d1 between the first electrode 11 and the first reverse surface 212 in the thickness direction z to the dimension t1 in the thickness direction z from the second reverse surface 312 to the second obverse surface 311 is, for example, 0.5% or more and 10% or less. When the first distance d1 is 5 μm or more and 30 μm or less as described above, the above dimension t1 is, for example, about 0.1 mm or more and 1 mm or less.

The constituent material of the second conductive bonding material 39 is not particularly limited and may be, for example, solder (a metal containing tin and silver). The second conductive bonding material 39 may also be constituted by metal paste containing a metal such as silver (Ag). Furthermore, a plating layer composed of silver (Ag) , for example, may be formed in the section of the first pad portion 31, the first bent portion 33, and the second bent portion 34 that is bonded to the semiconductor element 1 (second electrode 12).

The terminal portion 32 is connected to the x1 side in the first direction x with respect to the first bent portion 33. The terminal portion 32 extends in the first direction x as viewed in the thickness direction z. As shown in FIGS. 1, 2, 7, and 9, the terminal portion 32 includes: a portion connected to the first bent portion 33 and covered by the sealing resin 5; a portion protruding from the sealing resin 5 toward the x1 side in the first direction x; a portion folded back toward the z2 side in the thickness direction z; and a portion located on the z2 side in the thickness direction z. As viewed in the second direction y, the terminal portion 32 has a shape and size substantially overlapping the terminal portion 22. The terminal portion 32 is used as a terminal when mounting the semiconductor device A1. The terminal portion 32 is conducted to the second electrode 12 of the semiconductor element 1. The terminal portion 32 is the gate terminal of the semiconductor device A1.

A plating layer composed of an alloy including tin (Sn), for example, as its main component, may be formed on the portion of the second conductive member 3 (terminal portion 32) exposed from the sealing resin 5.

The third conductive member 4 is located on the z₂ side in the thickness direction z with respect to the semiconductor element 1. The third conductive member 4 contains a conductive material such as a metal, for example, copper (Cu).

As shown in FIGS. 1 to 10, the third conductive member 4 has an obverse surface 401 and a reverse surface 402. The obverse surface 401 faces the z₁ side in the thickness direction z. The reverse surface 402 faces the z₂ side in the thickness direction z. The semiconductor element 1 is mounted on the obverse surface 401. As shown in FIGS. 5 and 6, the reverse surface 402 is exposed from the sealing resin 5.

The third conductive member 4, as shown in FIGS. 1 to 10, has an island portion 41, a terminal portion 42, and a through hole 43.

The island portion 41 is the area where all or part of the semiconductor element 1 is mounted. The island portion 41 includes a part of the obverse surface 401 and a part of the reverse surface 402. The shape and size of the island portion 41 are not limited in any way; in the illustrated example, it is approximately rectangular as viewed in the thickness direction z.

As shown in FIGS. 2, 4, 6, and 8 to 10, the island portion 41 has a first edge portion 411, a second edge portion 412, a third edge portion 413, and a recessed groove 414. The first edge portion 411 is located on the y1 side in the second direction y and extends in the first direction x. The second edge portion 412 is located on the y2 side in the second direction y and extends in the first direction x. The third edge portion 413 is located on the x1 side in the first direction x and extends in the second direction y. The recessed groove 414 is recessed from the obverse surface 401 toward the z2 side in the thickness direction z and has a cross-section that is approximately V-shaped. The recessed groove 414 surrounds the semiconductor element 1 as viewed in the thickness direction z. The first edge portion 411, the second edge portion 412, the third edge portion 413, and the recessed groove 414 are each covered by the sealing resin 5. Note that, unlike the illustrated example, the island portion 41 may be configured without the recessed groove 414.

The first edge portion 411 has a first step portion 411a, as shown in FIGS. 4 and 6. The first step portion 411a is formed on the x2 side in the first direction x as compared to the semiconductor element 1. The first step portion 411a is shaped to be recessed toward the y2 side in the second direction y more on the x2 side in the first direction x than on the x1 side in the first direction x. In the present embodiment, the first step portion 411a is inclined with respect to both the first direction x and the second direction y such that, it extends toward the y2 side in the second direction y as it extends toward the x2 side in the first direction x.

The second edge portion 412 has a second step portion 412a. The second step portion 412a is formed on the x2 side in the first direction x with respect to the semiconductor element 1 in the first direction x. The second step portion 412a is shaped to be recessed toward the y1 side in the second direction y more on the x2 side in the first direction x than on the x1 side in the first direction x. In the present embodiment, the second step portion 412a is inclined with respect to both the first direction x and the second direction y such that, it extends toward the y1 side in the second direction y as it extends toward the x2 side in the first direction x.

In the present embodiment, the island portion 41 includes a main portion 41A, a first thin-walled portion 41B, and a second thin-walled portion 41C, as shown in FIGS. 4, 6, and 10. The main portion 41A has a portion of the obverse surface 401 and a portion of the reverse surface 402.

The first thin-walled portion 41B is the section connecting to the main portion 41A on the y1 side in the second direction y. The first thin-walled portion 41B includes a portion of the obverse surface 401 and a first intermediate surface 403. The first thin-walled portion 41B is a section that does not include a reverse surface 402. The first intermediate surface 403 faces the z2 side in the thickness direction z. The first intermediate surface 403 is located between the obverse surface 401 and the reverse surface 402 in the thickness direction z. Consequently, the first thin-walled portion 41B has a concave shape on the z2 side with respect to the main portion 41A in the thickness direction z. In the illustrated example, the first thin-walled portion 41B includes the entire first edge portion 411. The first step portion 411a is formed on the first thin-walled portion 41B.

The second thin-walled portion 41C is the section connecting to the main portion 41A on the y2 side in the second direction y. The second thin-walled portion 41C includes a portion of the obverse surface 401 and a second intermediate surface 404. The second thin-walled portion 41C is a section that does not include a reverse surface 402. The second intermediate surface 404 faces the z2 side in the thickness direction z. The second intermediate surface 404 is located between the obverse surface 401 and the reverse surface 402 in the thickness direction z. Consequently, the second thin-walled portion 41C has a concave shape on the z2 side with respect to the main portion 41A in the thickness direction z. In the illustrated example, the second thin-walled portion 41C includes the entire second edge portion 412. The second step portion 412a is formed on the second thin-walled portion 41C.

As shown in FIGS. 4, 10, etc., the semiconductor element 1 overlaps the main portion 41A and the first thin-walled portion 41B as viewed in the thickness direction z. Furthermore, the semiconductor element 1 overlaps the main portion 41A and the second thin-walled portion 41C as viewed in the thickness direction z.

As shown in FIGS. 8 to 10, the semiconductor element 1 is bonded to the obverse surface 401 of the island portion 41 via a conductive bonding material 19. The element second surface 102 of the semiconductor element 1 faces the obverse surface 401. The third electrode 13 on the element second surface 102 and the obverse surface 401 are conductively bonded via the conductive bonding material 19. The constituent material of the conductive bonding material 19 is not particularly limited and may be, for example, solder (a metal containing tin and silver). The conductive bonding material 19 may also be constituted by metal paste containing a metal such as silver (Ag). Furthermore, a plating layer composed of silver (Ag), for example, may be formed on the section of the obverse surface 401 of the island portion 41 where the semiconductor element 1 is bonded.

The terminal portion 42 is the section connected to the island portion 41 on the x2 side in the first direction x. The terminal portion 42 includes a part of the obverse surface 401 and a part of the reverse surface 402. The terminal portion 42 may be used as a terminal when mounting the semiconductor device A1. The terminal portion 42 is conducted to the third electrode 13 of the semiconductor element 1. The terminal portion 42 is the drain terminal of the semiconductor device A1.

The through hole 43 penetrates the third conductive member 4 in the thickness direction z. In the present embodiment, a portion of the sealing resin 5 is filled into the through hole 43. Furthermore, the size of the cross-section of the through hole 43 orthogonal to the thickness direction z is larger on the z2 side in the thickness direction z than on the z1 side. This, for example, serves to suppress the third conductive member 4 from detaching from the sealing resin 5.

A plating layer composed of an alloy including tin (Sn), for example, as its main component, may be formed on the portion of the third conductive member 4 exposed from the sealing resin 5.

The sealing resin 5 covers the semiconductor element 1 and a portion of each of the first conductive member 2, the second conductive member 3, and the third conductive member 4. The sealing resin 5 possesses electrical insulation properties. The sealing resin 5 includes, for example, a black epoxy resin containing filler. The shape of the sealing resin 5 is not limited in any way. As shown in FIGS. 1, 3 to 10, the sealing resin 5 of the present embodiment has a first resin surface 51, a second resin surface 52, a third resin surface 53, a fourth resin surface 54, a fifth resin surface 55, and a sixth resin surface 56.

The first resin surface 51 faces the z₁ side in the thickness direction z. The second resin surface 52 faces the z₂ side in the thickness direction z. The reverse surface 402 of the third conductive member 4 is exposed from the second resin surface 52. In the illustrated example, the first resin surface 51 and the second resin surface 52 are flat surfaces, but they are not limited thereto and may, for example, be curved surfaces or bent surfaces. In the illustrated example, the second resin surface 52 and the reverse surface 402 are coplanar.

The third resin surface 53 is a surface facing the x1 side in the first direction x. The fourth resin surface 54 is a surface facing the x2 side in the first direction x. In the illustrated example, the third resin surface 53 and the fourth resin surface 54 are surfaces that are slightly bent, but they are not limited to this configuration and may be, for example, curved surfaces or flat surfaces. In the present embodiment, a plurality of terminal portions 22 and terminal portion 32 protrude from the third resin surface 53, and terminal portion 42 protrudes from the fourth resin surface 54.

The fifth resin surface 55 is a surface facing the y1 side in the second direction y. The sixth resin surface 56 is a surface facing the y2 side in the second direction y. In the illustrated example, the fifth resin surface 55 and the sixth resin surface 56 are surfaces that are slightly bent, but they are not limited to this configuration and may be, for example, curved surfaces or flat surfaces.

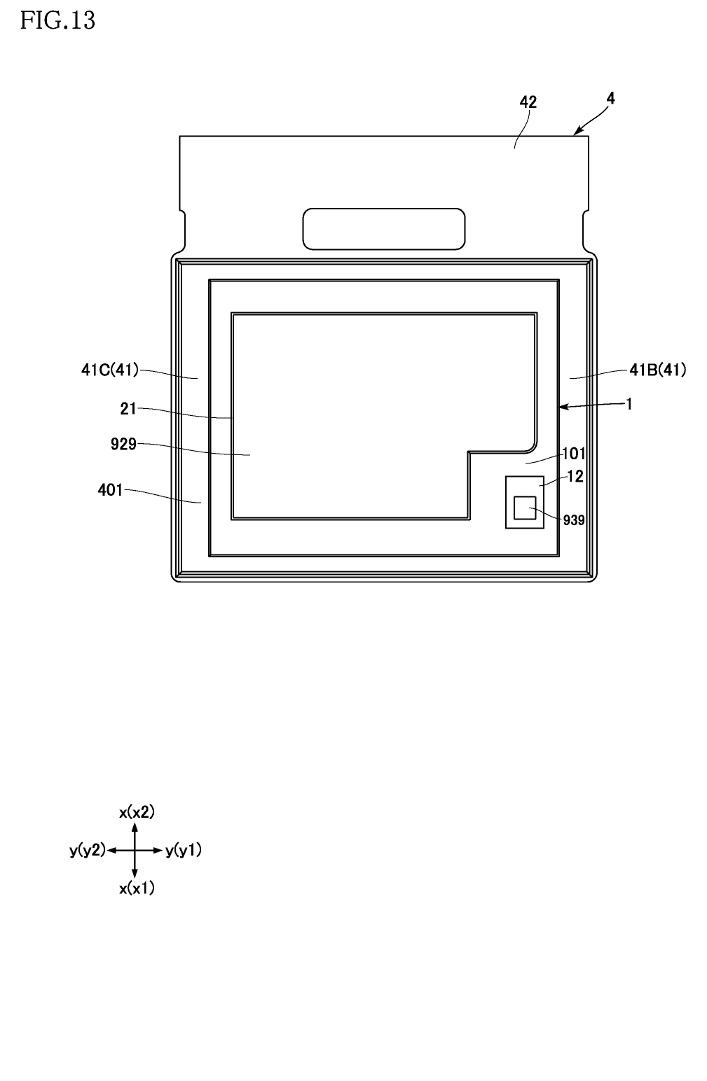

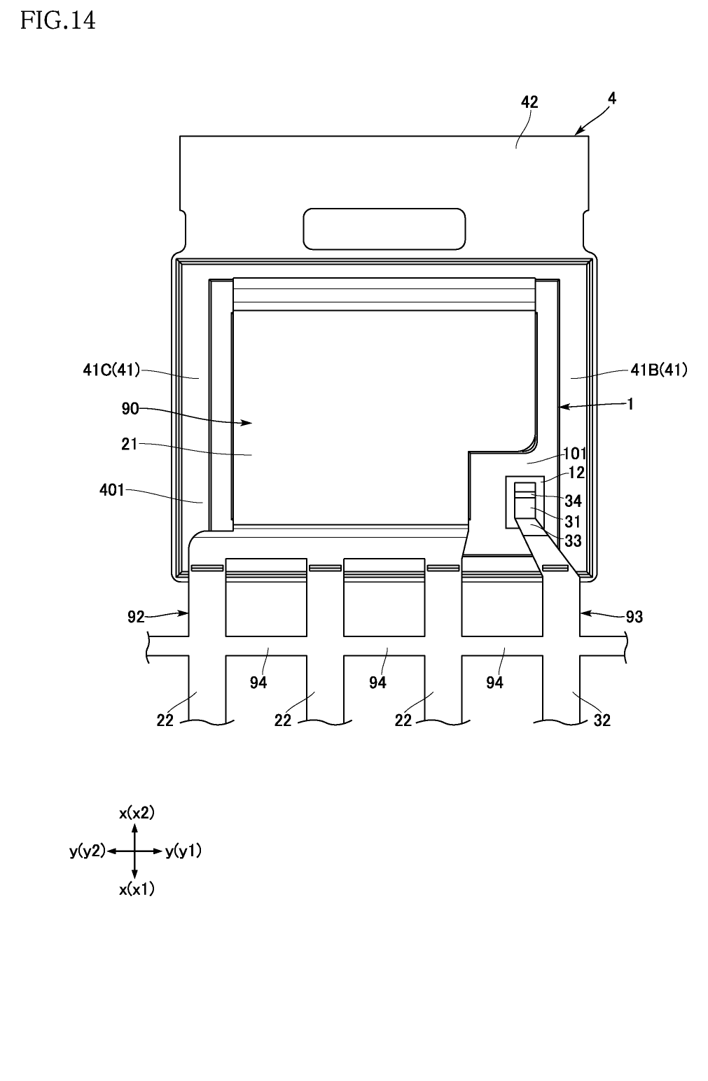

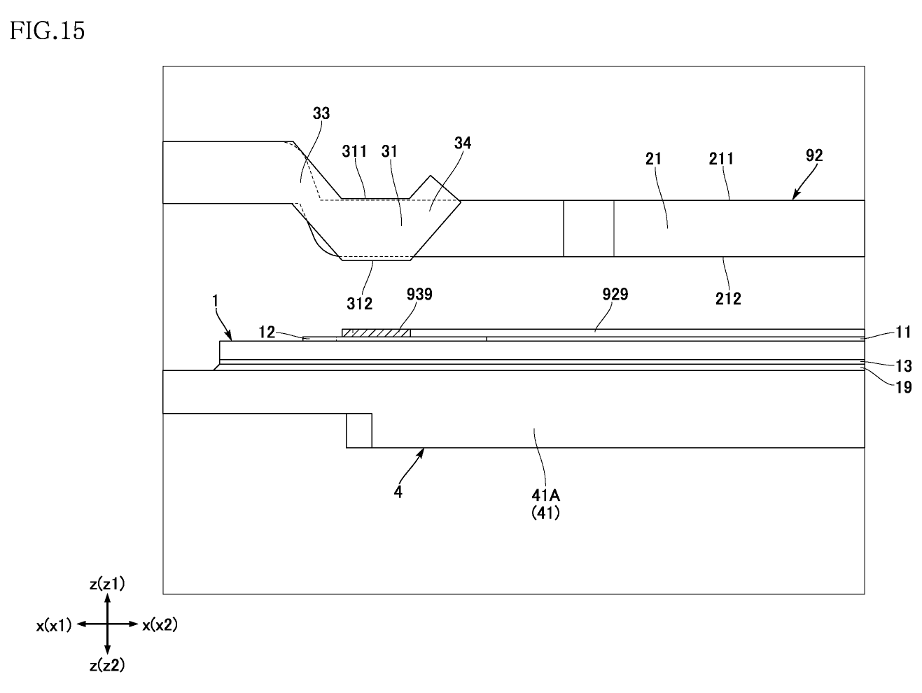

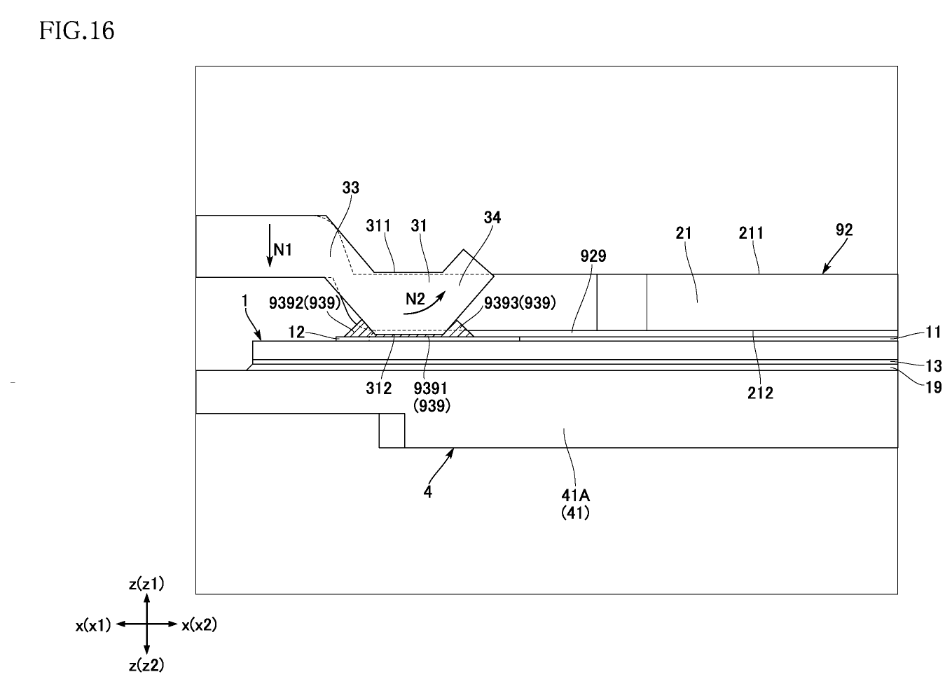

Next, an example of a manufacturing method for the semiconductor device A1 will be described below with reference to FIGS. 13 to 16. FIGS. 13 and 14 are plan views showing one process step during the manufacture of the semiconductor device A1. FIG. 15 is a partially enlarged side view of the process step shown in FIG. 14. FIG. 16 is a partially enlarged side view showing the process step following that in FIG. 15.

FIG. 13 shows the state where a first bonding layer 929 and a second bonding layer 939 are placed on the semiconductor element 1 mounted on the third conductive member 4. The first bonding layer 929 and the second bonding layer 939, which later become the first conductive bonding material 29 and the second conductive bonding material 39, are, for example, solder paste applied by a dispenser. Next, as shown in FIGS. 14 and 15, a metal clip member 90 is placed on the semiconductor element 1 at the z₁ side in the thickness z direction. The metal clip member 90 has a first conductive portion 92 and a second conductive portion 93 that are connected to each other. The first conductive portion 92 and second conductive portion 93 are the portions that later become the first conductive member 2 and second conductive member 3. They have a configuration where terminal portions 22 that are adjacent to each other, and a terminal portion 22 and the terminal portion 32 that are adjacent to each other are respectively connected via the connecting portion 94. Here, the first reverse surface 212 of the first conductive portion 92 (pad portion 21) overlaps the first bonding layer 929 as viewed in the thickness direction z. The second reverse surface 312 of the second conductive portion 93 (first pad portion 31) overlaps the second bonding layer 939 as viewed in the thickness direction z. Furthermore, as shown in FIG. 15, the first reverse surface 212 of the first conductive portion 92 (pad portion 21) is located on the z₂ side in the thickness direction z with respect to the second reverse surface 312 of the second conductive portion 93 (first pad portion 31). The distance between the first reverse surface 212 and the second reverse surface 312 in the thickness direction z is, for example, approximately 1 μm or more and 20 μm or less. Note that in FIG. 15 and FIG. 16 to be described later, hatching is applied to the second bonding layer 939 for ease of understanding.

Next, as shown in FIG. 16, while pressing the metal clip member 90 against the semiconductor element 1 toward the z₂ side in the thickness direction z (see arrow N1), the first bonding layer 929 and the second bonding layer 939 are heated to melt and then solidified. Here, the metal clip member 90 is pressed toward the z₂ side in the thickness direction z until the second reverse surface 312 receives a reaction force from the second electrode 12 (see arrow N2). At this stage, the second bonding layer 939 interposed between the second electrode 12 and the second reverse surface 312 is pushed out to the surrounding region, forming a thin portion 9391, a first portion 9392, and a second portion 9393. The distance between the second electrode 12 and the second reverse surface 312 then is smaller than the distance between the first electrode 11 and the first reverse surface 212. Subsequently, by forming the sealing resin 5 and appropriately cutting the connecting portion 94, etc., the plurality of terminal portions 22 and the terminal portion 32 are separated from one another. Afterwards, bending processing is applied to the plurality of terminal portions 22 and the terminal portion 32. In this manner, the first conductive member 2 and second conductive member 3 are formed.

Next, the operation of the semiconductor device A1 is described.

The semiconductor device A1 includes the first conductive bonding material 29 and the second conductive bonding material 39. The first conductive bonding material 29 is interposed between the first electrode 11 and the first reverse surface 212 of the first conductive member 2, and is bonded to the first electrode 11 and the first conductive member 2. The second conductive bonding material 39 is interposed between the second electrode 12 and the second reverse surface 312 of the second conductive member 3, and is bonded to the second electrode 12 and the second conductive member 3. The area of the second reverse surface 312 is smaller than the area of the first reverse surface 212. The distance (second distance d2) between the second electrode 12 and the second reverse surface 312 in the thickness direction z is smaller than the distance (first distance d1) between the first electrode 11 and the first reverse surface 212 in the thickness direction z. Such a configuration can stabilize the bonding state between the second electrode 12 whose area is relatively small and the second conductive member 3 bonded to it, thereby improving the bonding reliability.

The second conductive member 3 includes the first pad portion 31 having the second reverse surface 312, the first bent portion 33, and the second bent portion 34. The first bent portion 33 connects to the first pad portion 31 on the x1 side in the first direction x and extends toward the z1 side in the thickness direction z as it extends toward the x1 side in the first direction x. The second bent portion 34 connects to the first pad portion 31 on the x2 side in the first direction x and extends toward the z1 side in the thickness direction z as it extends toward the x2 side in the first direction x. The second conductive bonding material 39 includes the first portion 392 contacting the second electrode 12 and the first bent portion 33, and the second portion 393 contacting the second electrode 12 and the second bent portion 34. According to such a configuration, the bonding state between the second electrode 12 and the second conductive member 3 (first pad portion 31, first bent portion 33, and second bent portion 34) is stabilized with the reduced unevenness, making it more suitable for improving the bonding reliability. Furthermore, the inclination angle α1 of the first bent portion 33 with respect to the first direction x and the inclination angle α2 of the second bent portion 34 with respect to the first direction x are identical. This enables the first portion 392 contacting the first bent portion 33 and the second portion 393 contacting the second bent portion 34 to be formed more evenly in the first direction x. This is more favorable for improving the bonding reliability of the semiconductor device A1.

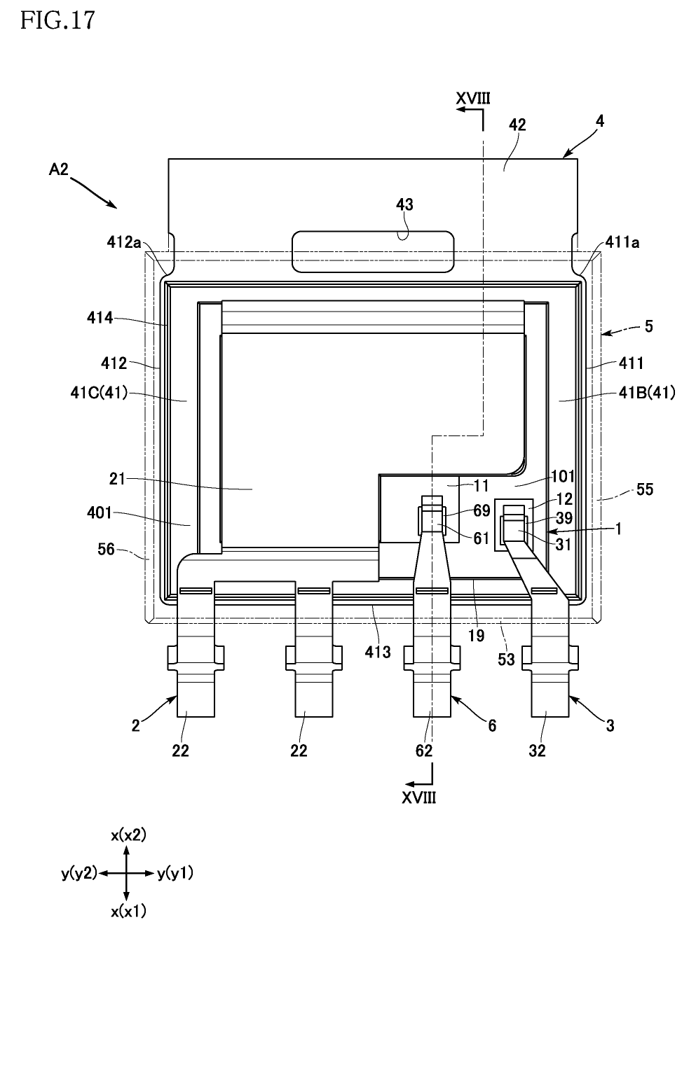

FIGS. 17 to 20 show other embodiments of the present disclosure. Note that in these figures, elements identical or similar to those in the above embodiment are designated by the same reference numerals as in the above embodiment, and redundant descriptions are omitted. Furthermore, the configurations of the respective parts in each embodiment can be appropriately combined with each other within the scope that does not cause technical contradictions.

### Second Embodiment:

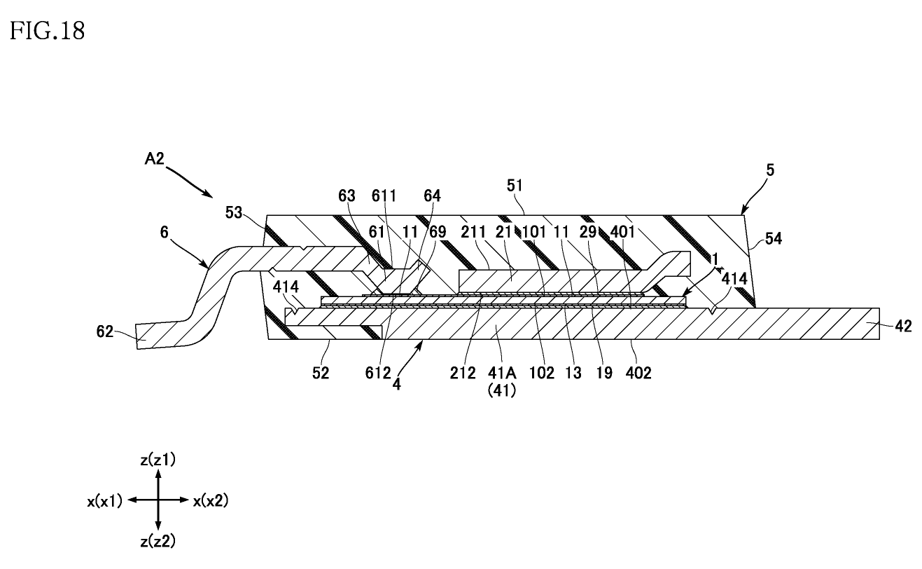

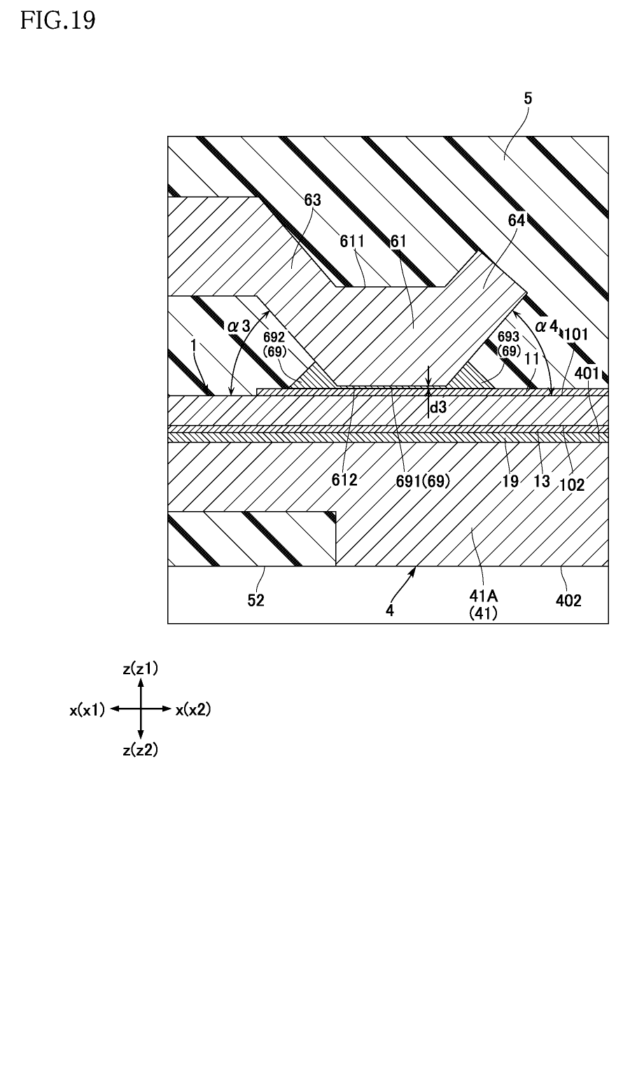

FIGS. 17 to 19 show a semiconductor device according to a second embodiment of the present disclosure. FIG. 17 is a plan view of main parts of the semiconductor device A2 of the present embodiment, showing the sealing resin 5 as being transparent. FIG. 18 is a cross-sectional view along line XVIII-XVIII of FIG. 17. FIG. 19 is a partially enlarged view of FIG. 18. Note that in FIG. 17, the sealing resin 5 in transparency is shown by an imaginary line (dash-dot-dot line).

The semiconductor device A2 further includes a fourth conductive member 6 and a third conductive bonding material 69, and accordingly, appropriate modifications have been made as compared to the semiconductor device A1. In the present embodiment, the pad portion 21 of the first conductive member 2 exposes a portion of the first electrode 11 (the corner portions on the x1 side in the first direction x and the y1 side in the second direction y). In the present embodiment, the first conductive member 2 has two terminal portions 22.

The fourth conductive member 6 is placed spaced apart from the second conductive member 3 in the second direction y. In the present embodiment, the fourth conductive member 6 is placed between the first conductive member 2 (terminal portion 22) and the second conductive member 3 in the second direction y. The fourth conductive member 6 includes a portion placed on the z₁ side in the thickness direction z with respect to the semiconductor element 1. The fourth conductive member 6 includes a conductive material such as metal and is constituted, for example, by a metal plate. The constituent material of the fourth conductive member 6 includes, for example, Cu (copper). The fourth conductive member 6 is a metal plate appropriately bent. The fourth conductive member 6 has a second pad portion 61, a terminal portion 62, a third bent portion 63, and a fourth bent portion 64.

The second pad portion 61 is the section conductively bonded to the first electrode 11 of the semiconductor element 1. The shape and size of the second pad portion 61 are not limited in any way. In the illustrated example, as viewed in the thickness direction z, it is shaped to overlap a part of the first electrode 11 and is also shaped to expose the first electrode 11.

As shown in FIGS. 18 and 19, the second pad portion 61 has a third obverse surface 611 and a third reverse surface 612. The third obverse surface 611 is a surface facing the z1 side in the thickness direction z. The third reverse surface 612 faces the z₂ side in the thickness direction z. The area of the third reverse surface 612 is smaller than the area of the first reverse surface 212 of the pad portion 21 in the first conductive member 2.

The third bent portion 63 connects to the second pad portion 61 on the x1 side in the first direction x. The third bent portion 63 is inclined such that it extends toward the z1 side in the thickness direction z as it extends toward the x1 side in the first direction x. The fourth bent portion 64 connects to the second pad portion 61 on the x2 side in the first direction x. The fourth bent portion 64 is inclined such that it extends toward the z₁ side in the thickness direction z as it extends toward the x₂ side in the first direction x. As shown in FIG. 19, the inclination angle α₃ of the third bent portion 63 with respect to the first direction x and the inclination angle α₄ of the fourth bent portion 64 with respect to the first direction x are identical. Here, "the inclination angle α₃ and the inclination angle α₄ are identical" means that the inclination angle α₃ and the inclination angle α₄ are designed to be identical, and includes cases where the inclination angle α₃ and the inclination angle α₄ differ due to manufacturing errors, etc. The inclination angles α₃ and α₄ are not particularly limited, but in the illustrated example, the inclination angles α₃ and α₄ are approximately 45°.

As shown in FIGS. 18 and 19, the second pad portion 61, the third bent portion 63, and the fourth bent portion 64 are bonded to the first electrode 11 of the semiconductor element 1 via the third conductive bonding material 69. The second pad portion 61, the third bent portion 63, and the fourth bent portion 64 are conductively bonded to the first electrode 11 via the third conductive bonding material 69. In the present embodiment, the third conductive bonding material 69 includes a thin portion 691, a third portion 692, and a fourth portion 693. The thin portion 691 is interposed between the first electrode 11 and the third reverse surface 612 in the thickness direction z and is the portion contacting the first electrode 11 and the third reverse surface 612. The third portion 692 is located on the x1 side in the first direction x with respect to the thin portion 691 and is the portion contacting the first electrode 11 and the third bent portion 63. The fourth portion 693 is located on the x2 side in the first direction x with respect to the thin portion 691 and is the portion contacting the first electrode 11 and the fourth bent portion 64.

The distance (third distance d₃) between the first electrode 11 and the third reverse surface 612 in the thickness direction z (see FIG. 19) is smaller than the distance (first distance d₁) between the first electrode 11 and the first reverse surface 212 in the thickness direction z (see FIG. 11). The third distance d3 between the first electrode 11 and the third reverse surface 612 in the thickness direction z is, for example, 1 μm or more and 20 μm or less. Note that the first electrode 11 and the third reverse surface 612 may partially contact each other.

The constituent material of the third conductive bonding material 69 is not particularly limited and is, for example, solder (a metal containing tin and silver). The third conductive bonding material 69 may also be constituted by metal paste containing a metal such as silver (Ag). Furthermore, a plating layer composed of silver (Ag), for example, may be formed in the section of the second pad portion 61, the third bent portion 63, and the fourth bent portion 64 that is bonded to the semiconductor element 1 (first electrode 11).

The terminal portion 62 is connected to the third bent portion 63 on the x1 side in the first direction x. The terminal portion 62 extends in the first direction x as viewed in the thickness direction z. As shown in FIGS. 17 and 18, the terminal portion 62 includes: a portion connected to the third bent portion 63 and covered by the sealing resin 5; a portion protruding from the sealing resin 5 toward the x1 side in the first direction x; a portion folded back toward the z2 side in the thickness direction z; and a portion located on the z2 side in the thickness direction z. As viewed in the second direction y, the terminal portion 62 has a shape and size substantially overlapping the terminal portion 22 and the terminal portion 32. The terminal portion 62 is used as a terminal when mounting the semiconductor device A1. The terminal portion 62 is conducted to the first electrode 11 of the semiconductor element 1. The terminal portion 62 is the source sense terminal of the semiconductor device A1.

The semiconductor device A2 of the present embodiment can be manufactured in the same manner as described above with reference to FIGS. 13 to 16 regarding the manufacturing method of the semiconductor device A1 of the above embodiment.

The semiconductor device A2 exhibits the same technical effects as the above semiconductor device A1. The semiconductor device A2 further includes the fourth conductive member 6 and the third conductive bonding material 69. The third conductive bonding material 69 is interposed between the first electrode 11 and the third reverse surface 612 of the fourth conductive member 6, and is bonded to both the first electrode 11 and the fourth conductive member 6. The area of the third reverse surface 612 is smaller than the area of the first reverse surface 212. The distance (third distance d3) between the first electrode 11 and the third reverse surface 612 in the thickness direction z is smaller than the distance (first distance d1) between the first electrode 11 and the first reverse surface 212 in the thickness direction z. According to such a configuration, the bonding state between the third reverse surface 612 (fourth conductive member 6) with a relatively small bonding area and the first electrode 11 bonded to it is stabilized, thereby improving the bonding reliability.

The fourth conductive member 6 includes the second pad portion 61 having the third reverse surface 612, the third bent portion 63, and the fourth bent portion 64. The third bent portion 63 connects to the second pad portion 61 on the x1 side in the first direction x and extends toward the z1 side in the thickness direction z as it extends toward the x1 side in the first direction x. The fourth bent portion 64 connects to the second pad portion 61 on the x2 side in the first direction x and extends toward the z1 side in the thickness direction z as it extends toward the x2 side in the first direction x. The third conductive bonding material 69 includes the third portion 692 contacting the first electrode 11 and the third bent portion 63, and the fourth portion 693 contacting the first electrode 11 and the fourth bent portion 64. According to such a configuration, the bonding state between the first electrode 11 and the fourth conductive member 6 (the second pad portion 61, the third bent portion 63, and the fourth bent portion 64) is stabilized with reduced unevenness, making it more suitable for improving the bonding reliability. Furthermore, the inclination angle α₃ of the third bent portion 63 with respect to the first direction x and the inclination angle α₄ of the fourth bent portion 64 with respect to the first direction x are identical. This enables the third portion 692 contacting the third bent portion 63 and the fourth portion 693 contacting the fourth bent portion 64 to be formed more evenly in the first direction x. This is more favorable for improving the bonding reliability of the semiconductor device A2.

### Third Embodiment:

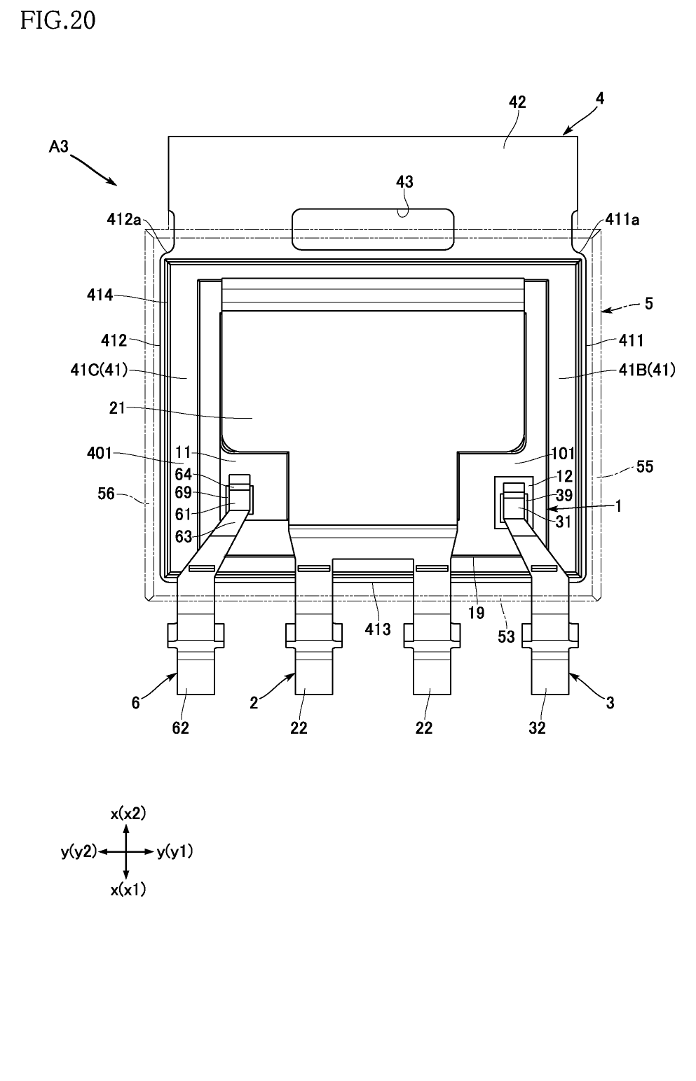

FIG. 20 shows a semiconductor device according to a third embodiment of the present disclosure. FIG. 20 is a plan view of main parts showing the semiconductor device A3 of the present embodiment, with the sealing resin 5 as being transparent. In FIG. 20, the sealing resin 5 in transparency is shown by imaginary lines (dash-dot-dot line).

The semiconductor device A3 of the present embodiment includes a fourth conductive member 6 and a third conductive bonding material 69, as the semiconductor device A2 described above. In the semiconductor device A3, the placement of the fourth conductive member 6 differs from that in the semiconductor device A2 described above. In the semiconductor device A3, the fourth conductive member 6 is placed on the y2 side in the second direction y, located on a side opposite the second conductive member 3 in the second direction y, with respect to the first conductive member 2. Although detailed illustration is omitted, the specific configuration of the fourth conductive member 6 and the third conductive bonding material 69 is the same as in the above semiconductor device A2. The semiconductor device A3 of the present embodiment can be manufactured in the same manner as described above with reference to FIGS. 13 to 16 regarding the manufacturing method of the semiconductor device A1 of the above embodiment. The semiconductor device A3 exhibits the same technical effects as the semiconductor devices A1 and A2 described above.

The semiconductor device according to the present disclosure is not limited to the above-described embodiments. The specific configurations of the various parts of the semiconductor device according to the present disclosure are subject to various design modifications.

The present disclosure includes the embodiments described in the following clauses.

Clause 1.

A semiconductor device comprising:

a semiconductor element having a first electrode and a second electrode located on a first side in a thickness direction;

a first conductive member being located on the first side in the thickness direction with respect to the first electrode, and having a first reverse surface to face a second side in the thickness direction;

a second conductive member being located on the first side in the thickness direction with respect to the second electrode, and having a second reverse surface to face the second side in the thickness direction;

a first conductive bonding material interposed between the first electrode and the first reverse surface, and bonded to the first electrode and the first conductive member; and

a second conductive bonding material interposed between the second electrode and the second reverse surface, and bonded to the second electrode and the second conductive member,

wherein an area of the second reverse surface is smaller than an area of the first reverse surface, and

a second distance between the second electrode and the second reverse surface in the thickness direction is smaller than a first distance between the first electrode and the first reverse surface in the thickness direction.

Clause 2.

The semiconductor device according to clause 1,

wherein the second conductive member comprises a first pad portion having a second reverse surface, a first bent portion being connected to the first pad portion on a first side in a first direction orthogonal to the thickness direction and extending toward the first side in the thickness direction as it extends toward the first side in the first direction, a second bent portion being connected to the first pad portion on a second side in the first direction and extending toward the second side in the thickness direction as it extends toward the second side in the first direction, and

the second conductive member comprises a first portion contacting the second electrode and the first bent portion, and a second portion contacting the second electrode and the second bent portion.

Clause 3.

The semiconductor device according to clause 2, wherein the inclination angle of the first bent portion with respect to the first direction and the inclination angle of the second bent portion with respect to the first direction are identical.

Clause 4.

The semiconductor device according to any one of clauses 1 to 3, wherein a constituent material of the first conductive bonding material and a constituent material of the second conductive bonding material include solder.

Clause 5.

The semiconductor device according to any one of clauses 1 to 4,

wherein the first conductive member and the second conductive member are constituted by metal plates,

the second conductive member has a second obverse surface overlapping the second reverse surface as viewed in the thickness direction and facing the first side in the thickness direction,

a ratio of the first distance to a dimension in the thickness direction from the second reverse surface to the second obverse surface is 0.5% or more and 10% or less

Clause 6.

The semiconductor device according to clause 5, wherein a constituent material of the first conductive member and a constituent material of the second conductive member include copper.

Clause 7.

The semiconductor device according to any one of clauses 1 to 6, wherein the first distance is 5 μm or more and 30 μm or less.

Clause 8.

The semiconductor device according to any one of clauses 1 to 7, further comprising a sealing resin covering the semiconductor element and at least a portion of each of the first conductive member and the second conductive member.

Clause 9.

The semiconductor device according to any one of clauses 1 to 8, further comprising a third conductive member,

wherein the semiconductor element has a third electrode placed on the second side in the thickness direction,

the third conductive member is placed on the second side in the thickness direction with respect to the semiconductor element and is conductively bonded to the third electrode.

Clause 10.

The semiconductor device according to clause 9,

wherein the semiconductor element is a switching element having a drain electrode, a source electrode, and a gate electrode, and

the first electrode is the source electrode, the second electrode is the gate electrode, and the third electrode is the drain electrode.

Clause 11.

The semiconductor device according to clause 10, further comprising:

a fourth conductive member being located on the first side in the thickness direction with respect to the first electrode, and having a third reverse surface facing the second side in the thickness direction; and

a third conductive bonding material interposed between the first electrode and the third reverse surface, and bonded to the first electrode and the fourth conductive member,

wherein an area of the third reverse surface is smaller than the area of the first reverse surface, and

a third distance between the first electrode and the third reverse surface in the thickness direction is smaller than the first distance.

Clause 12.

The semiconductor device according to clause 11,

wherein the fourth conductive member comprises a second pad portion having the third reverse surface, a third bent portion being connected to the second pad portion on the first side in the first direction and extending toward the first side in the thickness direction as it extends toward the first side in the first direction, and a fourth bent portion connected to the second pad portion on the second side in the first direction and extends toward the second side in the thickness direction as it extends toward the second side in the first direction, and

the third conductive bonding material comprises a third portion contacting the first electrode and the third bent portion, and a fourth portion contacting the first electrode and the fourth bent portion.

Clause 13.

The semiconductor device according to clause 11 or 12, wherein the fourth conductive member is spaced apart from the second conductive member in a second direction orthogonal to the thickness direction and the first direction.

Clause 14.

The semiconductor device according to clause 13, wherein the fourth conductive member is located on a side opposite the second conductive member in the second direction, with respect to the first conductive member.

Clause 15.

A method for manufacturing a semiconductor device, comprising steps of:

placing, with respect to a semiconductor element having a first electrode and a second electrode arranged on a first side in a thickness direction, a first bonding layer and a second bonding layer on the first electrode and the second electrode;

placing a metal clip member having a first conductive portion and a second conductive portion connected to each other on the semiconductor element at the first side in the thickness direction; and

heating and melting the first bonding layer and the second bonding layer while pressing the metal clip member against the semiconductor element toward a second side in the thickness direction, and solidifying them,

wherein the first conductive portion has a first reverse surface facing the second side in the thickness direction and overlapping the first bonding layer as viewed in the thickness direction,

the second conductive portion has a second reverse surface facing the second side in the thickness direction and overlapping the second bonding layer as viewed in the thickness direction,

the second reverse surface is located on the second side in the thickness direction with respect to the first reverse surface, and

in the step of heating and melting the first bonding layer and the second bonding layer and solidifying them, the metal clip member is pressed toward the second side in the thickness direction until the second reverse surface receives a reaction force from the second electrode.

REFERENCE NUMERALS

A1, A2, A3: Semiconductor device 1: Semiconductor element

101: Element first surface 102: Element second surface

11: First electrode 12: Second electrode

13: Third electrode 19: Conductive bonding material

2: First conductive member 21: Pad portion

211: First obverse surface 212: First reverse surface

22: Terminal portion 29: First conductive bonding material

3: Second conductive member 31: First pad portion

311: Second obverse surface 312: Second reverse surface

32: Terminal portion 33: First bent portion

34: Second bent portion 39: Second conductive bonding material

391: Thin portion 392: First portion

393: Second portion 4: Third conductive member

401: Obverse surface 402: Reverse surface

403: First intermediate surface 404: Second intermediate surface

41: Island portion 41A: Main portion

41B: First thin-walled portion 41C: Second thin-walled portion

411: First edge portion 411a: First step portion

412: Second edge portion 412a: Second step portion

413: Third edge portion 414: Recessed groove

42: Terminal portion 43: Through hole

5: Sealing resin 51: First resin surface

52: Second resin surface 53: Third resin surface

54: Fourth resin surface 55: Fifth resin surface

56: Sixth resin surface 6: Fourth conductive member

61: Second pad portion 611: Third obverse surface

612: Third reverse surface 62: Terminal portion

63: Third bent portion 64: Fourth bent portion

69: Third conductive bonding material 691: Thin portion

692: Third portion 693: Fourth portion

90: Metal clip member 92: First conductive portion

929: First bonding layer 93: Second conductive portion

939: Second bonding layer 9391: Thin portion

9392: First portion 9393: Second portion

94: Connecting portion α1, α2, α3, α4: Inclination angle

d1: First distance d2: Second distance

d3: Third distance t1: Dimension

1. A semiconductor device comprising:
a semiconductor element having a first electrode and a second electrode located on a first side in a thickness direction;
a first conductive member being located on the first side in the thickness direction with respect to the first electrode, and having a first reverse surface to face a second side in the thickness direction;
a second conductive member being located on the first side in the thickness direction with respect to the second electrode, and having a second reverse surface to face the second side in the thickness direction;
a first conductive bonding material interposed between the first electrode and the first reverse surface, and bonded to the first electrode and the first conductive member; and
a second conductive bonding material interposed between the second electrode and the second reverse surface, and bonded to the second electrode and the second conductive member,
wherein an area of the second reverse surface is smaller than an area of the first reverse surface, and
a second distance between the second electrode and the second reverse surface in the thickness direction is smaller than a first distance between the first electrode and the first reverse surface in the thickness direction.

2. The semiconductor device according to claim 1,
wherein the second conductive member comprises a first pad portion having a second reverse surface, a first bent portion being connected to the first pad portion on a first side in a first direction orthogonal to the thickness direction and extending toward the first side in the thickness direction as it extends toward the first side in the first direction, a second bent portion being connected to the first pad portion on a second side in the first direction and extending toward the second side in the thickness direction as it extends toward the second side in the first direction, and
the second conductive member comprises a first portion contacting the second electrode and the first bent portion, and a second portion contacting the second electrode and the second bent portion.

3. The semiconductor device according to claim 2, wherein the inclination angle of the first bent portion with respect to the first direction and the inclination angle of the second bent portion with respect to the first direction are identical.

4. The semiconductor device according to claim 1, wherein a constituent material of the first conductive bonding material and a constituent material of the second conductive bonding material include solder.

5. The semiconductor device according to claim 1,
wherein the first conductive member and the second conductive member are constituted by metal plates,
the second conductive member has a second obverse surface overlapping the second reverse surface as viewed in the thickness direction and facing the first side in the thickness direction,
a ratio of the first distance to a dimension in the thickness direction from the second reverse surface to the second obverse surface is 0.5% or more and 10% or less.

6. The semiconductor device according to claim 5, wherein a constituent material of the first conductive member and a constituent material of the second conductive member include copper.

7. The semiconductor device according to claim 1, wherein the first distance is 5 μm or more and 30 μm or less.

8. The semiconductor device according to claim 1, further comprising a sealing resin covering the semiconductor element and at least a portion of each of the first conductive member and the second conductive member.

9. The semiconductor device according to claim 1, further comprising a third conductive member,
wherein the semiconductor element has a third electrode placed on the second side in the thickness direction,
the third conductive member is placed on the second side in the thickness direction with respect to the semiconductor element and is conductively bonded to the third electrode.

10. The semiconductor device according to claim 9,
wherein the semiconductor element is a switching element having a drain electrode, a source electrode, and a gate electrode, and
the first electrode is the source electrode, the second electrode is the gate electrode, and the third electrode is the drain electrode.

11. The semiconductor device according to claim 10, further comprising:
a fourth conductive member being located on the first side in the thickness direction with respect to the first electrode, and having a third reverse surface facing the second side in the thickness direction; and
a third conductive bonding material interposed between the first electrode and the third reverse surface, and bonded to the first electrode and the fourth conductive member,
wherein an area of the third reverse surface is smaller than the area of the first reverse surface, and
a third distance between the first electrode and the third reverse surface in the thickness direction is smaller than the first distance.

12. The semiconductor device according to claim 11,
wherein the fourth conductive member comprises a second pad portion having the third reverse surface, a third bent portion being connected to the second pad portion on the first side in the first direction and extending toward the first side in the thickness direction as it extends toward the first side in the first direction, and a fourth bent portion connected to the second pad portion on the second side in the first direction and extends toward the second side in the thickness direction as it extends toward the second side in the first direction, and
the third conductive bonding material comprises a third portion contacting the first electrode and the third bent portion, and a fourth portion contacting the first electrode and the fourth bent portion.

13. The semiconductor device according to claim 11, wherein the fourth conductive member is spaced apart from the second conductive member in a second direction orthogonal to the thickness direction and the first direction.

14. The semiconductor device according to claim 13, wherein the fourth conductive member is located on a side opposite the second conductive member in the second direction, with respect to the first conductive member.

15. A method for manufacturing a semiconductor device, comprising steps of:
placing, with respect to a semiconductor element having a first electrode and a second electrode arranged on a first side in a thickness direction, a first bonding layer and a second bonding layer on the first electrode and the second electrode;
placing a metal clip member having a first conductive portion and a second conductive portion connected to each other on the semiconductor element at the first side in the thickness direction; and
heating and melting the first bonding layer and the second bonding layer while pressing the metal clip member against the semiconductor element toward a second side in the thickness direction, and solidifying them,
wherein the first conductive portion has a first reverse surface facing the second side in the thickness direction and overlapping the first bonding layer as viewed in the thickness direction,
the second conductive portion has a second reverse surface facing the second side in the thickness direction and overlapping the second bonding layer as viewed in the thickness direction,
the second reverse surface is located on the second side in the thickness direction with respect to the first reverse surface, and
in the step of heating and melting the first bonding layer and the second bonding layer and solidifying them, the metal clip member is pressed toward the second side in the thickness direction until the second reverse surface receives a reaction force from the second electrode.
